(19) United States
(12) Patent Application Publication
(10) Pub. No.: US 2005/0098798 A1
(43) Pub. Date: May 12, 2005

(54) Semiconductor integrated circuit device in which terminal capacitance is adjustable

(76) Inventors: Makoto Miyazawa, Kanagawa (JP); Kenshi Izumi, Kanagawa (JP)

Correspondence Address: KATTEN MUCHIN ZAVIS ROSENMAN, 575 MADISON AVENUE, NEW YORK, NY, 10022-2585, US

(21) Appl. No.: 10/628,500

(22) Filed: Jul. 28, 2003

(30) Foreign Application Priority Data
Jul. 26, 2002 (JP) 218748/2002

(51) Int. Cl. H01L 31/0328

(52) U.S. Cl. 257/200

(57) ABSTRACT

A semiconductor integrated circuit device includes a terminal and a first capacitance adjusting section. The first capacitance adjusting section is connected to a wiring between the terminal and a protection resistor in front stage of an internal circuit. The first capacitance adjusting section adjusts terminal capacitance of the terminal, based on capacitance of the first capacitance adjusting section. The semiconductor integrated circuit device may further includes a protection circuit which is connected to the wiring between the terminal and the first capacitance adjusting section and protects the internal circuit.

### BACKGROUND OF THE INVENTION

1. Field of the Invention

The present invention relates to a semiconductor integrated circuit device, and more particularly relates to a semiconductor integrated circuit device in which terminal capacitance is adjustable.

2. Description of the Related Art

In recent years, an operational frequency has been higher in a semiconductor integrated circuit device. In association with it, requests have been strict for an allowable range of a variation and an absolute value of a hold time and a setup time to an input signal and an output signal. In order to satisfy the requests, the allowable maximum and minimum values of the terminal capacitance are defined for the semiconductor integrated circuit device in the recent years. Also, a semiconductor chip as one of semiconductor integrated circuit devices is sealed within a plurality of types of different packages, in many cases.

Incidentally, the layout of wirings from external terminals of the semiconductor integrated circuit device to bonding pads inside the semiconductor chip is different for each package type. Thus, the terminal capacitance is different for each package type.

FIG. 1 is a table showing an example of the terminal capacitance. As shown in FIG. 1, the terminal capacitance is 1.00 pF in TSOP (Thin Small Out-line Package), and 0.14 pF in CSP (Chip Size Package).

So, in the semiconductor integrated circuit device in the recent years, the idea to satisfy the request specification for the terminal capacitance is employed even if the package type is changed.

FIGS. 2A and 2B is a circuit diagram showing the conventional example technique of adjusting the terminal capacitance. A plurality of kinds of terminal capacitance adjusting capacitors 118 are formed in advance between a protection resistance 103 and an input circuit 104. The protection resistance 103 is connected to a bonding pad 101. Then, in a wiring process, the connections of the terminal capacitance adjusting capacitors 118 are changed for the capacitance adjustment by a capacitor switching section 129 such that the terminal capacitance satisfies the specification.

Also, a process variation may cause an estimated value of the terminal capacitance at a designing stage to be slightly different from an actually measured value after a trial production (after an evaluation). However, even for this problem, similarly to the above-mentioned case, in a wiring process, the connections of the terminal capacitance adjusting capacitors 118 are changed for the capacitance adjustment by a capacitor switching section 129 such that the terminal capacitance satisfies the specification.

However, the above-mentioned conventional method needs to re-design the wiring process and re-produce a reticle in order to adjust the terminal capacitance, which leads to the increase in a development cost and makes a development period longer.

Japanese Laid Open Patent Application (JP-A 2000-31386) discloses a semiconductor device to solve the above-mentioned problems. FIG. 3 is a circuit diagram showing the conventional technique of the semiconductor device. In the semiconductor device, as shown in FIG. 3, the terminal capacitance adjusting capacitors 118 are connected to wiring 105 through the capacitor switching section 129 and protection resistance 103. The wiring 105 connected to a bonding pad 101 is branched to an input circuit 104 as a wiring 130a and to terminal capacitance adjusting capacitors 118 as a wiring 130b, respectively, after the ESD protection circuit 120. An excessive capacitance is not added to a wiring 130a connected to the input circuit 104. Therefore, a delay in a signal transmitted to the input circuit 104 is reduced.

Also, Japanese Laid Open Patent Application (JP-A 2000-208707) (corresponding to Japanese Patent No.3043735) discloses a semiconductor device in which a terminal capacitance can be controlled. FIG. 4 is a circuit diagram showing the conventional technique of the semiconductor device. In the semiconductor device, as shown in FIG. 4, an ESD element 131 is used as a terminal capacitance adjusting capacitor, and a terminal capacitance value is adjusted by controlling a potential of a P-well of the ESD element 131. Also, the potential of the P-well can be adjusted by using a switching signal generating section 135 having a fuse 132 and a resistance element 133, a SUB potential switching section 136 having a resistance element 133 and a N-type MOSFET 134 and a negative potential generating circuit 110. More concretely, the potential of the P-well can be adjusted by cutting the fuse 132. Thus, the terminal capacitance can be adjusted even after the completion of diffusion.

In conjunction with the above description, the technique of the semiconductor integrated circuit device is disclosed in Japanese Laid Open Patent Application (JP-A-Heisei 6-85174). The object of this technique is to reduces noise among wirings for a power supply, and to improve electrostatic voltage proof of the wirings each of which was connected with each power supply pin (or the grounding pin), in an IC with a plurality of the power supply pins (or the grounding pins).

The semiconductor integrated circuit device of this technique includes a plurality of power supply terminals (, or grounding terminals) and power supply wirings (or grounding wirings). The power supply terminals (or a grounding terminals) are provided onto the semiconductor chip. Each of the power supply wirings (or the grounding wirings) connects with each of the power supply terminals (or the grounding terminals), and moreover it is arranged independently each other. A parasitic MOSFET is connected between power supply wirings (or grounding wirings).

The technique of the protection circuit of the electrostatic discharge, the transistor and the semiconductor device which equipped with this is disclosed in Japanese Laid Open Patent Application (JP-A-Heisei 11-168181). The problem of this technique is that when the electrostatic discharge is generated, the substrate electric current flows from the parasitic well and the parasitic NPN transistor is excited magnetically, which causes latch up. Also the capacitance of the parasitic well sometimes brings about an antenna effect and brings about interference with the switching form.

The protection circuit of the electrostatic discharge of this technique is integrated on an integrated circuit. The integrated circuit includes at least one input terminal and at least one output terminal, respectively.

The protection circuit includes at least one transistor (Q1) that has a first terminal, a second terminal and a control terminal. As for the transistor, one of the first terminal and the second terminal is connected with one of the input terminal and the output terminal and the other one of the first terminal and the second terminal is connected with an electric power supply wiring of the integrated circuit respectively.

The control terminal is connected with the ground of the integrated circuit.

The technique of the display unit with the voltage generating circuit and the voltage generating circuit is disclosed in Japanese Laid Open Patent Application (JP-A 2001-251847). The object of this technique is to provide the voltage generating circuit which can obtain high reaching voltage to the request and has the ability for the high electric current drive.

The voltage generating circuit of this technique includes a capacitor and generates fixed voltage through the node which is connected with one of the terminals of the capacitor. It includes the n channel transistor and the p channel transistor. As for the n channel transistor, one of the source terminal and the drain terminal is connected with the node and the other is a voltage output terminal. As for the p channel transistor, one of the source terminal and the drain terminal is connected with the node and the other is a standard potential terminal. Each gate terminal of the n channel transistor and the p channel transistor is connected with each other. Clock signals with each other reversed phase are inputted respectively into the gate terminals connected with each other and the other terminal of the capacitor.

However, in the semiconductor device disclosed in JP-A 2000-31386 shown in FIG. 3, the number of protection resistors 103 is required correspondingly to the number of the branches, which causes the increase of a chip size. Also, even in this semiconductor device, the terminal capacitance value is adjusted by the method similar to the above-mentioned conventional method shown in FIGS. 2A and 2B. Thus, in order to adjust the terminal capacitance, it is necessary to re-design the wiring process and re-produce the reticle.

In the semiconductor device disclosed in JP-A 2000-208707 shown in FIG. 4, a production variation in a resistor 33 is different from a variation in a threshold of an N-type MOSFET 34. Thus, this difference brings about the deviation from a desired potential, which results in a problem that the compensation for the terminal capacitance is deviated from the desired value.

### SUMMARY OF THE INVENTION

Therefore, an object of the present invention is to provide a semiconductor integrated circuit device, in which a terminal capacitance can be accurately adjusted.

Another object of the present invention is to provide a semiconductor integrated circuit device, in which a terminal capacitance can be accurately adjusted in a short time and at a cheap price without any increase of a chip size.

Still another object of the present invention is to provide a semiconductor integrated circuit device, in which a delay time of the input signals can be reduced.

In order to achieve an aspect of the present invention, the present invention provides a semiconductor integrated circuit device including: a terminal and a first capacitance adjusting section. The first capacitance adjusting section is connected to a wiring between the terminal and a protection resistor in front stage of an internal circuit. The first capacitance adjusting section adjusts terminal capacitance of the terminal, based on capacitance of the first capacitance adjusting section.

The semiconductor integrated circuit device of the present invention further includes a protection circuit which is connected to the wiring between the terminal and the first capacitance adjusting section and protects the internal circuit.

In the semiconductor integrated circuit device of the present invention, the first capacitance adjusting section includes a first adjusting capacitor which adjusts the terminal capacitance. The first adjusting capacitor includes a first semiconductive portion and a second conductive portion. The first conductive portion is composed of a first well region formed in a substrate with the internal circuit and having a conductive type opposite to that of the substrate. The second semiconductive portion is opposite to the first semiconductive portion and is composed of a first diffusion layer region formed in the first well region and having the same conductive type as that of the substrate.

The semiconductor integrated circuit device of the present invention, further includes a well potential control section. The first capacitance adjusting section further includes a second adjusting capacitor which adjusts the terminal capacitance based on controlling a well region potential by the well potential control section. The second adjusting capacitor includes a third semiconductive portion and a fourth conductive portion. The third conductive portion is composed of a second well region formed in the substrate and having a conductive type opposite to that of the substrate. The fourth semiconductive port ion which is opposite to the third semiconductive portion and is composed of a second diffusion layer region formed in the second well region and having the same conductive type as that of the substrate. The well potential control section controls the well region potential of the second well region.

In the semiconductor integrated circuit device of the present invention, the well potential control section includes: a plurality of resistors and a plurality of switches. The plurality of resistors is connected in series to each other between two potential electrodes. Each of the plurality of switches is connected in parallel to each of the plurality of resistors. The well potential control section controls the well region potential by controlling each one of the plurality of switches.

The semiconductor integrated circuit device of the present invention, further includes a plurality of the terminals and a plurality of the first capacitance adjusting sections. Each of the plurality of the first capacitance adjusting sections is connected to the wiring between each of the plurality of terminals and each of a plurality of the protection resistors. The well potential control section controls each of a plurality of the well region potentials.

In the semiconductor integrated circuit device of the present invention, the first capacitance adjusting section includes a first adjusting capacitor which adjusts the terminal capacitance. The first adjusting capacitor includes a first semiconductive portion and a second semiconductive portion. The first semiconductive portion is composed of a first well region formed in a substrate with the internal circuit and having a conductive type opposite to that of the substrate. The second semiconductive portion is opposite to the first semiconductivee portion and is composed of a first diffusion layer region formed in the first well region and having the same conductive type as that of the substrate.

The semiconductor integrated circuit device of the present invention, further includes a well potential control section. The first capacitance adjusting section further includes a second adjusting capacitor which adjusts the terminal capacitance based on controlling a well region potential by the well potential control section. The second adjusting capacitor includes a third semiconductive portion and a fourth semiconductive portion. The third semiconductive portion is composed of a second well region formed in the substrate and having a conductive type opposite to that of the substrate. The fourth semiconductive portion is opposite to the third semiconductive portion and is composed of a second diffusion layer region formed in the second well region and having the same conductive type as that of the substrate. The well potential control section controls the well region potential of the second well region.

In the semiconductor integrated circuit device of the present invention, the well potential control section includes a plurality of resistors and a plurality of switches. The plurality of resistors is connected in series to each other between two potential electrodes. Each of the plurality of switches is connected in parallel to each of the plurality of resistors. The well potential control section controls the well region potential by controlling each one of the plurality of switches.

The semiconductor integrated circuit device of the present invention, further includes a plurality of the terminals and a plurality of the first capacitance. Each of the plurality of the first capacitance adjusting sections is connected to each of a plurality of the wirings between each of the plurality of terminals and each of a plurality of the protection resistors. The well potential control section controls each of a plurality of the well region potentials.

The semiconductor integrated circuit device of the present invention, further includes a second capacitance adjusting section and a switching control section. The second capacitance adjusting section is connected to a wiring between the first capacitance adjusting section and the internal circuit. The second capacitance adjusting section adjusts the terminal capacitance based on capacitance of the second capacitance adjusting section. The switching control section controls the capacitance of the second capacitance adjusting section.

In the semiconductor integrated circuit device of the present invention, the switching control section includes: a plurality of switches and a plurality of signal holding sections. Each of the plurality of switches outputs signal potentials corresponding to turn on and off of the each of plurality of switches. Each of the plurality of signal holding sections holds a corresponding each of a plurality of the signal potentials. The switching control section controls the capacitance of the second capacitance adjusting section based on the plurality of signal potentials.

In the semiconductor integrated circuit device of the present invention, the second capacitance adjusting section includes a plurality of third adjusting capacitors each of which capacitance is variable based on corresponding the each of the plurality of signal potentials. The second capacitance adjusting section adjusts the plurality of third adjusting capacitors based on the plurality of signal potentials.

The semiconductor integrated circuit device of the present invention, further includes a plurality of the terminals and a plurality of the second capacitance adjusting sections. Each of the plurality of the second capacitance adjusting sections is connected to each of a plurality of the wirings between each of the plurality of the first capacitance adjusting sections and each of a plurality of the internal circuits. The switching control section controls each of a plurality of the capacitances of the plurality of second capacitance adjusting sections.

The semiconductor integrated circuit device of the present invention, further includes a second capacitance adjusting section and a switching control section. The second capacitance adjusting section is connected to a wiring between the first capacitance adjusting section and the internal circuit. The second capacitance adjusting section adjusts the terminal capacitance based on capacitance of the second capacitance adjusting section. The switching control section which controls the capacitance of the second capacitance adjusting section.

In the semiconductor integrated circuit device of the present invention, the switching control section includes a plurality of switches and a plurality of signal holding sections. Each of the plurality of switches outputs signal potentials corresponding to turn on and off of the each of plurality of switches. Each of the plurality of signal holding sections holds corresponding each of a plurality of the signal potentials. The switching control section controls the capacitance of the second capacitance adjusting section based on the plurality of signal potentials.

In the semiconductor integrated circuit device of the present invention, the second capacitance adjusting section includes a plurality of third adjusting capacitors each of which capacitance is variable based on corresponding the each of the plurality of signal potentials. The second capacitance adjusting section adjusts the plurality of third adjusting capacitors based on the signal potential.

The semiconductor integrated circuit device of the present invention, further includes a plurality of the terminals and a plurality of the second capacitance adjusting sections. Each of the plurality of the second capacitance adjusting sections is connected to each of a plurality of the wirings between each of the plurality of the first capacitance adjusting sections and each of a plurality of the internal circuits. The switching control section controls each of a plurality of the capacitances of the plurality of second capacitance adjusting sections.

### BRIEF DESCRIPTION OF THE DRAWINGS

FIG. 1 is a table showing an example of the terminal capacitance;

FIGS. 2A and 2B is a circuit diagram showing the conventional example technique of adjusting the terminal capacitance;

FIG. 3 is a circuit diagram showing the conventional technique of the semiconductor device;

FIG. 4 is a circuit diagram showing the conventional technique of the semiconductor device;

FIG. 5A is a circuit diagram showing a configuration of a first embodiment of a semiconductor integrated circuit device according to the present invention;

FIG. 5B is another circuit diagram showing a configuration of a first embodiment of a semiconductor integrated circuit device according to the present invention;

FIG. 6 is a plan view showing the first and second terminal capacitance adjusting capacitors 6a and 6b;

FIG. 7 is a sectional view showing the first and second terminal capacitance adjusting capacitors 6a and 6b along the line A-A shown in FIG. 6;

FIG. 8 is a graph showing the relation between the capacitance of the second terminal capacitance adjusting capacitor 6b and the potential (BIAS) of the well 12b;

FIGS. 9 to 11 are block diagrams showing the other configurations of the semiconductor integrated circuit device according to the first embodiment of the present invention;

FIG. 12 is a circuit diagram showing a configuration of the second embodiment of the semiconductor integrated circuit device according to the present invention;

FIG. 13 is a graph showing an example of change of the potential;

FIG. 14 is a table showing the total values of the capacitance of the terminal capacitance adjusting section 24;

FIGS. 15 to 17 are block diagrams showing the configuration of the semiconductor integrated circuit device according to the second embodiment of the present invention;

FIG. 18 is a circuit diagram showing a configuration of the third embodiment of the semiconductor integrated circuit device according to the present invention;

FIG. 19 is a circuit diagram showing a configuration of the fourth embodiment of the semiconductor integrated circuit device according to the present invention;

FIG. 20 is a circuit diagram showing a configuration of the fifth embodiment of the semiconductor integrated circuit device according to the present invention;

FIG. 21 is a block diagram showing a configuration of another embodiment of the semiconductor integrated circuit device according to the present invention; and

FIG. 22 is a view showing the comparison between the terminal capacitance when the conventional technique is used and the terminal capacitance when the technique according to the present invention is used.

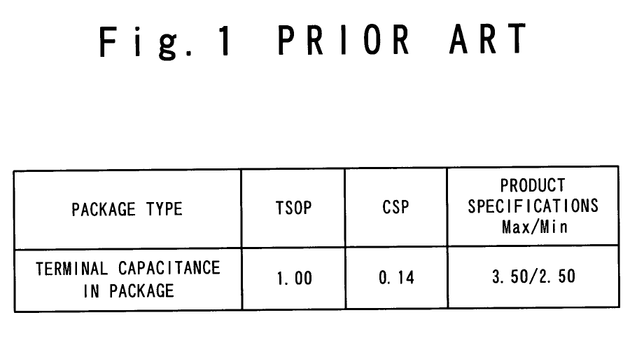

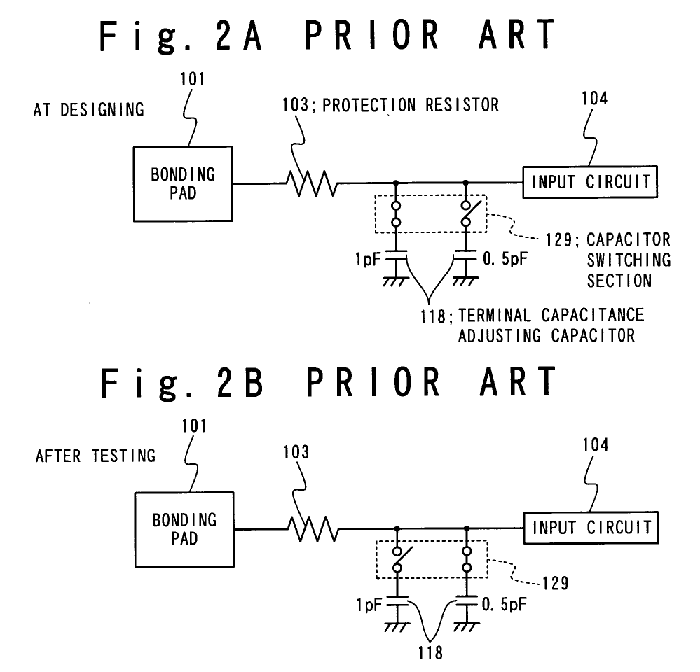

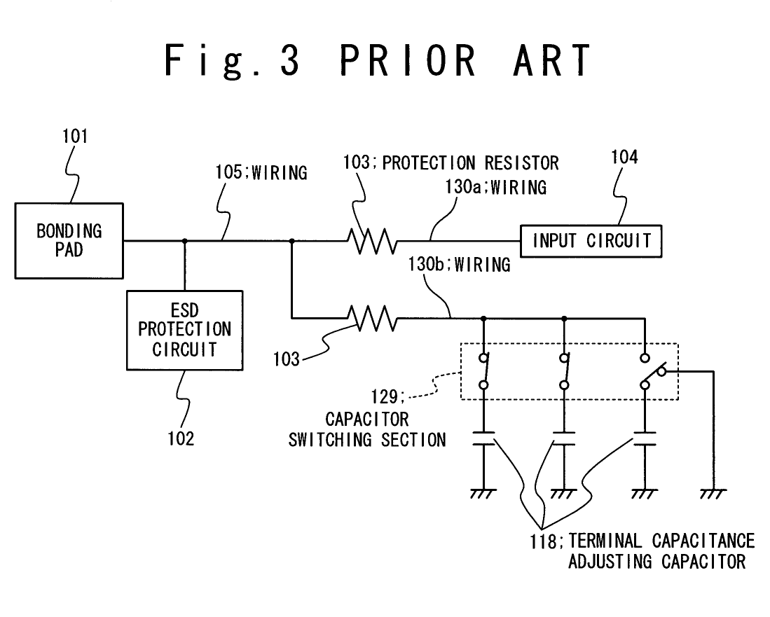

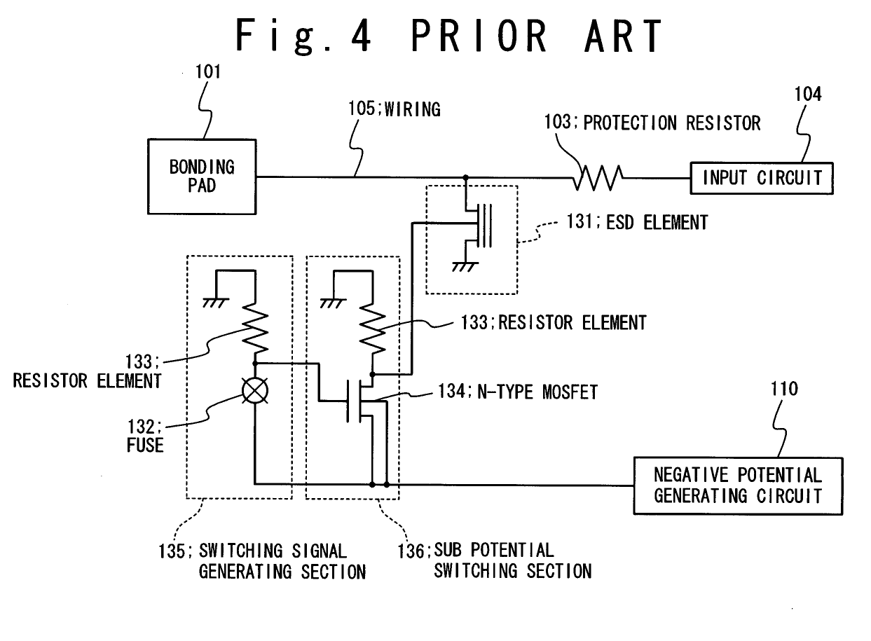

### DESCRIPTION OF THE PREFERRED EMBODIMENTS

Embodiments of a semiconductor integrated circuit device according to the present invention will be described below with reference to the attached drawings.

### First Embodiment

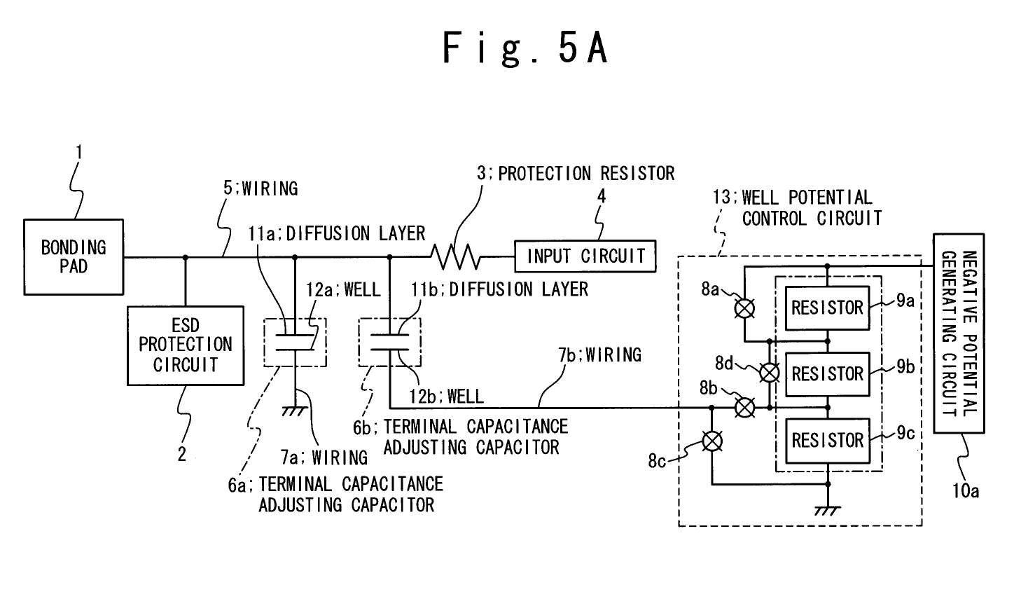

FIG. 5A is a circuit diagram showing a configuration of a first embodiment of a semiconductor integrated circuit device according to the present invention. Here, an input unit of the semiconductor integrated circuit device is shown in FIG. 5A. This input unit includes a bonding pad 1, an ESD protection circuit 2, a protection resistor 3, an input circuit 4, a first terminal capacitance adjusting capacitor 6a, a second terminal capacitance adjusting capacitor 6b, a negative potential generating circuit 10a and a well potential control circuit 13. The first terminal capacitance adjusting capacitor 6a is composed of a diffusion layer 11a and a well 12a. The second terminal capacitance adjusting capacitor 6b is composed of a diffusion layer 11b and a well 12b.

The bonding pad 1, the ESD protection circuit 2, one end of the protection resistor 3 and the diffusion layers 11a and 11b are mutually connected through a wiring 5. The well 12a is grounded through a wiring 7a. The well 12b is connected through a wiring 7b to the well potential control circuit 13. The well potential control circuit 13 is connected to the negative potential generating circuit 10a. Also, the other end of the protection resistor 3 is connected to the input circuit 4.

The negative potential generating circuit 10a generates potential from zero to negative potential when the well 12b has P-type and the Si substrate 16 has N-type. In this case, the lower (negative side) limit of the potential is just before the break down voltage between the diffusion layer 11b and the well 12b.

The well potential control circuit 13 is composed of fuses 8a, 8b, 8c and 8d and resistors 9a, 9b and 9c for controlling a well potential. The resistors 9a, 9b and 9c are connected in series in this order. One end of the resistor 9a is connected to the negative potential generating circuit 10a. One end of the resistor 9c is grounded The fuse 8a is connected in parallel to the resistor 9a, and the fuse 8d is connected in parallel to the resistor 9b. Also, the serially connected fuses 8b and 8c are connected in parallel to the resistor 9c. Then, a connection point between the fuses 8b and 8c is connected to the well 12b.

The well potential control circuit 13 divides the potential of the negative potential generating circuit 10a by the resistors 9a to 9c based on cutting or not cutting the fuses 8a to 8d such that the well potential control circuit 13 outputs the desirable potential as a bias potential to the terminal capacitance adjusting capacitor 6b.

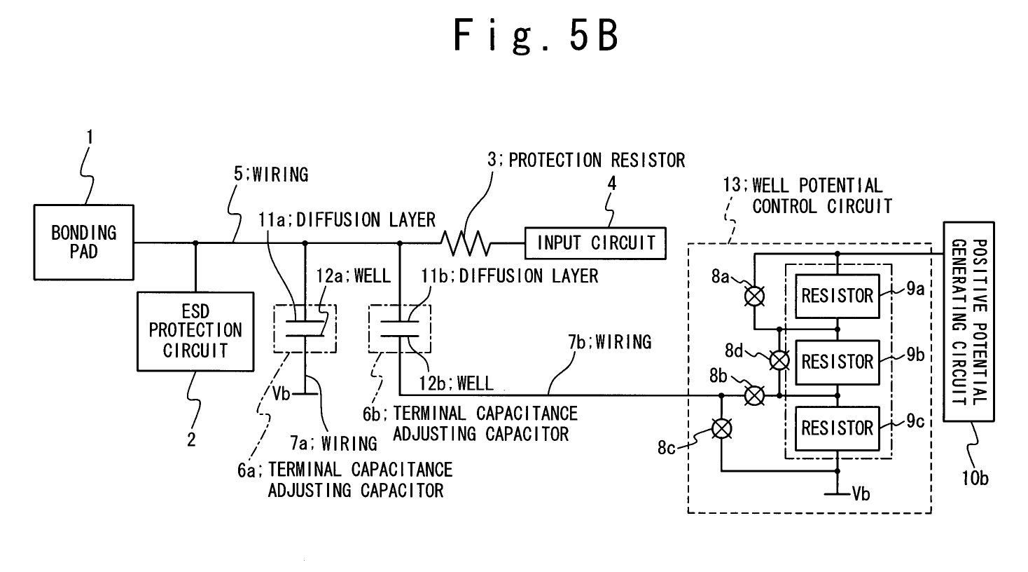

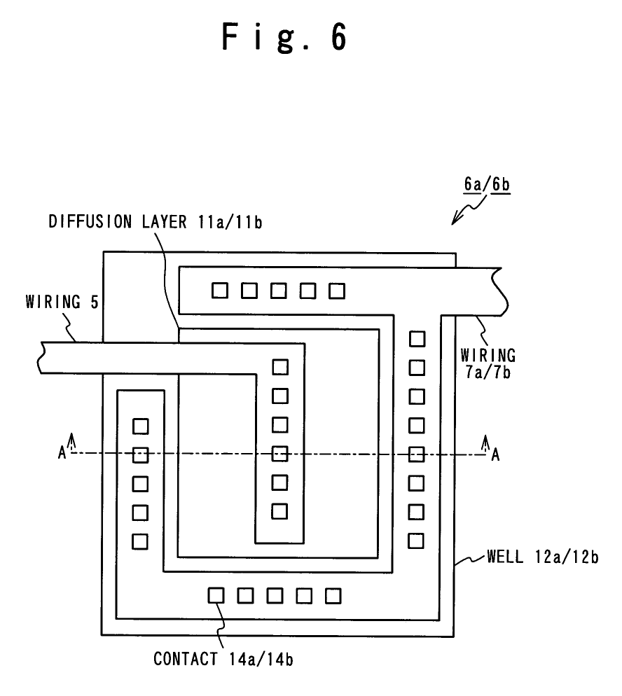

FIG. 6 is a plan view showing the first and second terminal capacitance adjusting capacitors 6a and 6b. And FIG. 7 is a sectional view showing the first and second terminal capacitance adjusting capacitors 6a and 6b along the line A-A shown in FIG. 6.

As shown in FIGS. 6 and 7, the first terminal capacitance adjusting capacitors 6a includes a diffusion layer region (hereafter, merely referred to as “diffusion layer”) 11a, and a well region (hereafter, merely referred to as “well”) 12a. The diffusion layer 11a has the same conductive type as that of a silicon substrate 16, and is formed within the well 12a. The well 12a has the conductive type opposite to that of the silicon substrate 16, and is formed on the silicon (Si) substrate 16. The well 12a is connected through a diffusion layer 15a and a contact 14a to the wiring 7a. The diffusion layer 11a is connected through a contact 14a to the wiring 5. The diffusion layer 15a has the same conductive type as that of the well 12a and is highly doped for contacting.

The first terminal capacitance adjusting capacitor 6a is the capacitor having a terminal capacitance value commonly requested for respective package types.

Also, as shown in FIGS. 6 and 7, the second terminal capacitance adjusting capacitors 6b includes a diffusion layer 11b, and a well 12b. The diffusion layer 11b has the same conductive type as that of the silicon substrate 16, and is formed within the well 12b. The well 12b has the conductive type opposite to that of the silicon substrate 16, and is formed on the silicon (Si) substrate 16. The well 12b is connected through a diffusion layer 15b and a contact 14b to the wiring 7b. The diffusion layer 11b is connected through a contact 14b to the wiring 5. The diffusion layer 15b has the same conductive type as that of the well 12b and is highly doped for contacting.

The second terminal capacitance adjusting capacitor 6b is the capacitor for adjusting the difference of the terminal capacitance value between the respective package types.

The bias potential outputted from the well potential control circuit 13 controls the width of depletion layer D such that the capacitance between the diffusion layer 11b and the well 12b is desirably changed.

The operation of the input unit of the semiconductor integrated circuit device according to the first embodiment of the present invention will be described below with reference to the drawings.

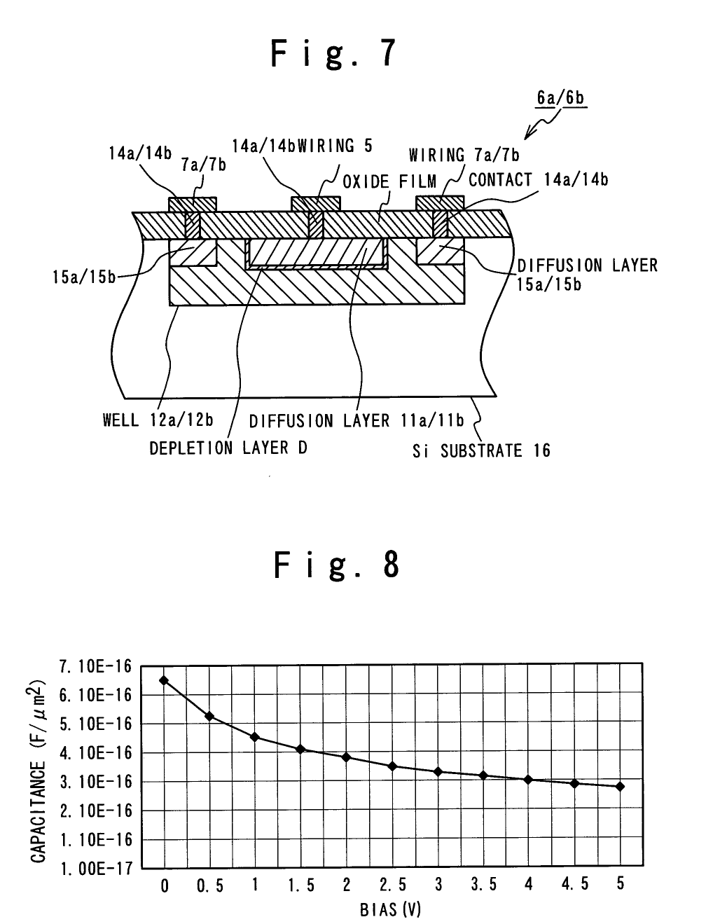

In FIG. 5, since the well 12a of the first terminal capacitance adjusting capacitor 6a is grounded, the capacitance value is constant. The potential (BIAS) of the well 12b of the second terminal capacitance adjusting capacitor 6b is adjusted by controlling the resistance value between the negative potential generating circuit 10a and the grounded potential. The resistance value between the negative potential generating circuit 10a and the grounded potential is controlled by suitably cutting the fuses 8a, 8b, 8c and 8d in the well potential control circuit 13. FIG. 8 is a graph showing the relation between the capacitance of the second terminal capacitance adjusting capacitor 6b and the potential (BIAS) of the well 12b. The vertical axis shows the potential (BIAS) of the well 12b, and the horizontal axis shows the capacitance of the second terminal capacitance adjusting capacitor 6b. As shown in FIG. 8, it can be understood that the capacitance of the second terminal capacitance adjusting capacitor 6b is changed based on the potential of the well 12b. Thus, the capacitance value of the second terminal capacitance adjusting capacitor 6b can be adjusted by changing the potential of the well 12b. Hence, the capacitance of the terminal (bonding pad 1) in the semiconductor integrated circuit device can be adjusted to a desirable value.

Incidentally, the potential of the negative potential generating circuit 10a may be desirably set to obtain the desirable potential. Also, the number of resistors 9 and the number of fuses 8 may be desirably set to obtain desirable steps of the bias potential. Furthermore, the number of sets of the second terminal capacitance adjusting capacitor 6b *and its related configurations is not limited to 2, and it may be arbitrary.

In this embodiment, P-type and N-type of the semiconductors such as the Si substrate 16, the diffusion layer 11a/11b and the well 12a/12b can be exchanged. In this case, the configuration shown in FIG. 5A is changed to that shown in FIG. 5B. FIG. 5B is another circuit diagram showing a configuration of a first embodiment of a semiconductor integrated circuit device according to the present invention.

Here, the positive potential generating circuit 10b is used instead of the negative potential generating circuit 10a in FIG. 5A. The wiring 7a is connected to Vd (positive potential such as supply voltage)

The positive potential generating circuit 10b generates potential from Vd (positive potential) to positive potential larger than Vd when the well 12b has N-type and the Si substrate 16 has P-type. In this case, the upper (positive side) limit of the potential is just before the break down voltage between the diffusion layer 11b and the well 12b.

Other configurations shown in FIG. 5B are the same as those shown in FIG. 5A.

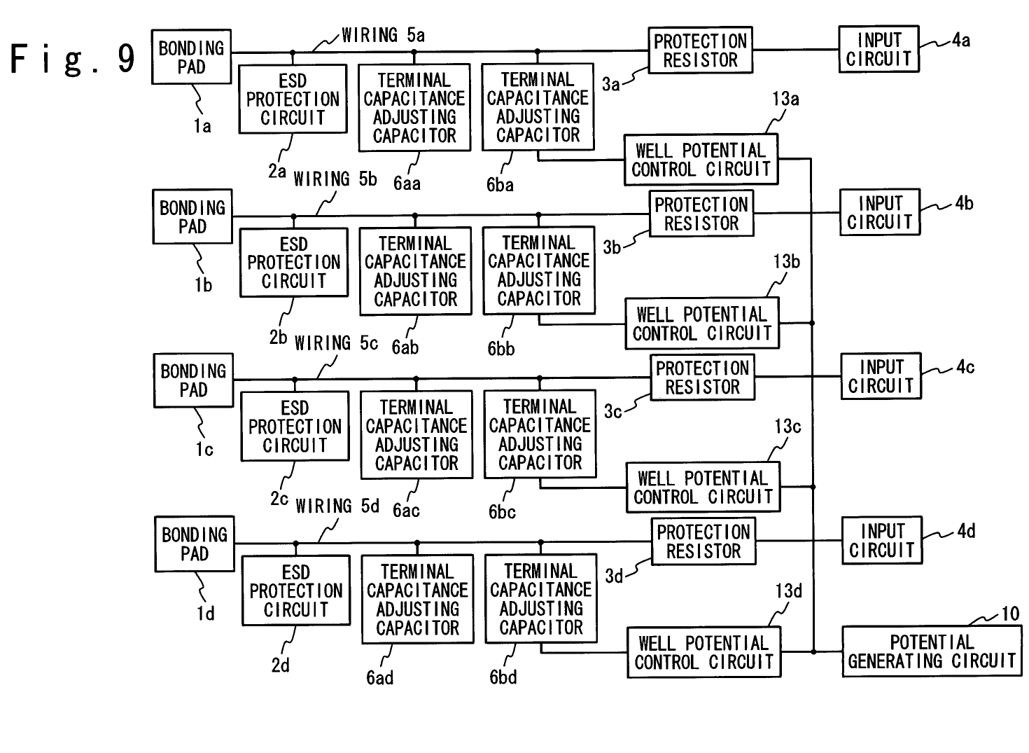

FIGS. 9 to 11 are block diagrams showing the other configurations of the semiconductor integrated circuit device according to the first embodiment of the present invention, which is constituted by using the circuit shown in FIG. 5A or FIG. 5B. In case of using the circuit shown in FIG. 5A, the potential generating circuit 10 is the negative potential generating circuit 10a. In case of using the circuit shown in FIG. 5B, the potential generating circuit 10 is the positive potential generating circuit 10b.

The semiconductor integrated circuit device shown in FIG. 9 is designed such that the terminal capacitance value can be adjusted for each terminal by installing the circuit shown in FIG. 5A or 5B for each terminal (bonding pad 1). This semiconductor integrated circuit device includes: bonding pads 1a, 1b, 1c and 1d; ESD protection circuits 2a, 2b, 2c and 2d; first terminal capacitance adjusting capacitors 6aa, 6ab, 6ac and 6ad; second terminal capacitance adjusting capacitors 6ba, 6bb, 6bc and 6bd; protection resistors 3a, 3b, 3c and 3d; input circuits 4a, 4b, 4c and 4d; well potential control circuits 13a, 13b, 13c and 13d; and a potential generating circuit 10.

The bonding pad 1a, the ESD protection circuit 2a, one end of the protection resistor 3a, the first terminal capacitance adjusting capacitor 6aa and the second terminal capacitance adjusting capacitor 6ba are mutually connected through a wiring 5a. The other end of the protection resistor 3a is connected to the input circuit 4a. The second terminal capacitance adjusting capacitor 6ba is connected to the well potential control circuit 13a. The well potential control circuit 13a is connected to the potential generating circuit 10.

Similarly, the bonding pad 1b, the ESD protection circuit 2b, one end of the protection resistor 3b, the first terminal capacitance adjusting capacitor 6ab and the second terminal capacitance adjusting capacitor 6bb are mutually connected through a wiring 5b. The other end of the protection resistor 3b is connected to the input circuit 4b. The second terminal capacitance adjusting capacitor 6bb is connected to the well potential control circuit 13b. The well potential control circuit 13b is connected to the potential generating circuit 10.

Similarly, the bonding pad 1c, the ESD protection circuit 2c, one end of the protection resistor 3c, the first terminal capacitance adjusting capacitor 6ac and the second terminal capacitance adjusting capacitor 6bc are mutually connected through a wiring 5c. The other end of the protection resistor 3c is connected to the input circuit 4c. The second terminal capacitance adjusting capacitor 6bc is connected to the well potential control circuit 13c. The well potential control circuit 13c is connected to the potential generating circuit 10.

Similarly, the bonding pad 1d, the ESD protection circuit 2d, one end of the protection resistor 3d, the first terminal capacitance adjusting capacitor 6ad and the second terminal capacitance adjusting capacitor 6bd are mutually connected through a wiring 5d. The other end of the protection resistor 3d is connected to the input circuit 4d. The second terminal capacitance adjusting capacitor 6bd is connected to the well potential control circuit 13d. The well potential control circuit 13d is connected to the potential generating circuit 10.

Due to the above-mentioned configuration, the terminal capacitance can be adjusted for each terminal by suitably cutting the fuses included in the respective well potential control circuits 13a, 13b, 13c and 13d. Incidentally, FIG. 9 illustrates the configuration when the terminal capacitances are adjusted for the four terminals. However, the number of the terminals is not limited to 4, and it is arbitrary.

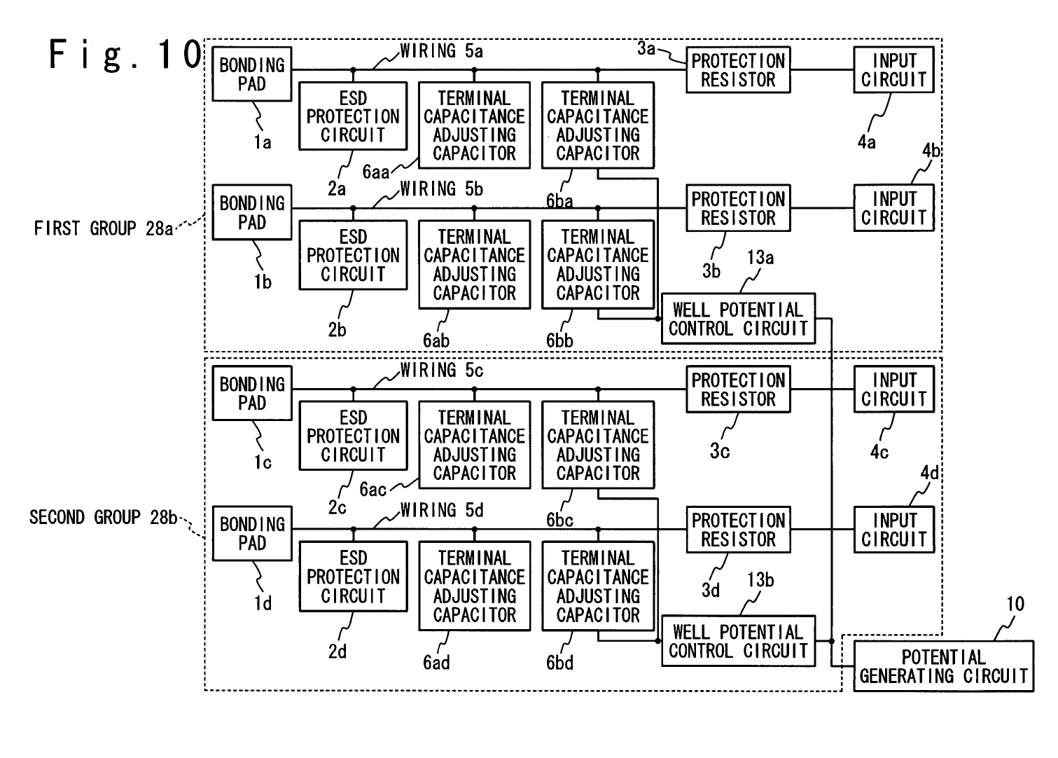

The semiconductor integrated circuit device shown in FIG. 10 includes a first group 28a and a second group 28b designed such that the terminal capacitance value can be adjusted for each terminal group. The terminal capacitance value can be adjusted by installing the circuits except the well potential control circuit 13 among the circuits shown in FIG. 5A or 5B for each terminal and installing the well potential control circuit 13 for each terminal group.

The first group 28a is composed of: bonding pads 1a and 1b; ESD protection circuits 2a and 2b; first terminal capacitance adjusting capacitors 6aa and 6ab; second terminal capacitance adjusting capacitors 6ba and 6bb; protection resistors 3a and 3b; input circuits 4a and 4b; and a well potential control circuit 13a.

The second group 28b is composed of: bonding pads 1c and 1d; ESD protection circuits 2c and 2d; first terminal capacitance adjusting capacitors 6ac and 6ad; second terminal capacitance adjusting capacitors 6bc and 6bd; protection resistors 3c and 3d; input circuits 4c and 4d; and a well potential control circuit 13b. Incidentally, the potential generating circuit 10 is commonly used in the first group 28a and the second group 28b. In case of using the circuit shown in FIG. 5A, the potential generating circuit 10 is the negative potential generating circuit 10a. In case of using the circuit shown in FIG. 5B, the potential generating circuit 10 is the positive potential generating circuit 10b.

As for the first group 28a, the bonding pad 1a, the ESD protection circuit 2a, one end of the protection resistor 3a, the first terminal capacitance adjusting capacitor 6aa and the second terminal capacitance adjusting capacitor 6ba are mutually connected through a wiring 5a. The other end of the protection resistor 3a is connected to the input circuit 4a. The second adjusting capacitor 6ba is connected to the well potential control circuit 13a. The well potential control circuit 13a is connected to the potential generating circuit 10.

Similarly, the bonding pad 1b, the ESD protection circuit 2b, one end of the protection resistor 3b, the first terminal capacitance adjusting capacitor 6ab and the second terminal capacitance adjusting capacitor 6bb are mutually connected through a wiring 5b. The other end of the protection resistor 3b is connected to the input circuit 4b. The second adjusting capacitor 6bb is connected to the well potential control circuit 13a.

As for the second group 28b, the bonding pad 1c, the ESD protection circuit 2c, one end of the protection resistor 3c, the first terminal capacitance adjusting capacitor 6ac and the second terminal capacitance adjusting capacitor 6bc are mutually connected through a wiring 5c. The other side of the protection resistor 3c is connected to the input circuit 4c. The adjusting capacitor 6bc is connected to the well potential control circuit 13b. The well potential control circuit 13b is connected to the potential generating circuit 10.

Similarly, the bonding pad 1d, the ESD protection circuit 2d, one end of the protection resistor 3d, the first terminal capacitance adjusting capacitor 6ad and the second terminal capacitance adjusting capacitor 6bd are mutually connected through a wiring 5d. The other end of the protection resistor 3d is connected to the input circuit 4d. The adjusting capacitor 6bd is connected to the well potential control circuit 13b.

Due to the above-mentioned configuration, the terminal capacitance can be adjusted for each group by suitably cutting the fuses included in each of the well potential control circuit 13a of the first group 28a and the well potential control circuit 13b of the second group 28b. Thus, the capacitance value can be adjusted by grouping the respective terminals in which the differences of the capacitance values peculiar to the package types are approximately equal.

Incidentally, the semiconductor integrated circuit device shown in FIG. 10 is explained under the assumption that one group includes the two terminals, and the number of the groups is 2. However, the number of the terminals included in the group is not limited to 2, and it is arbitrary. Also, the number of the groups is not limited to 2, and it is arbitrary.

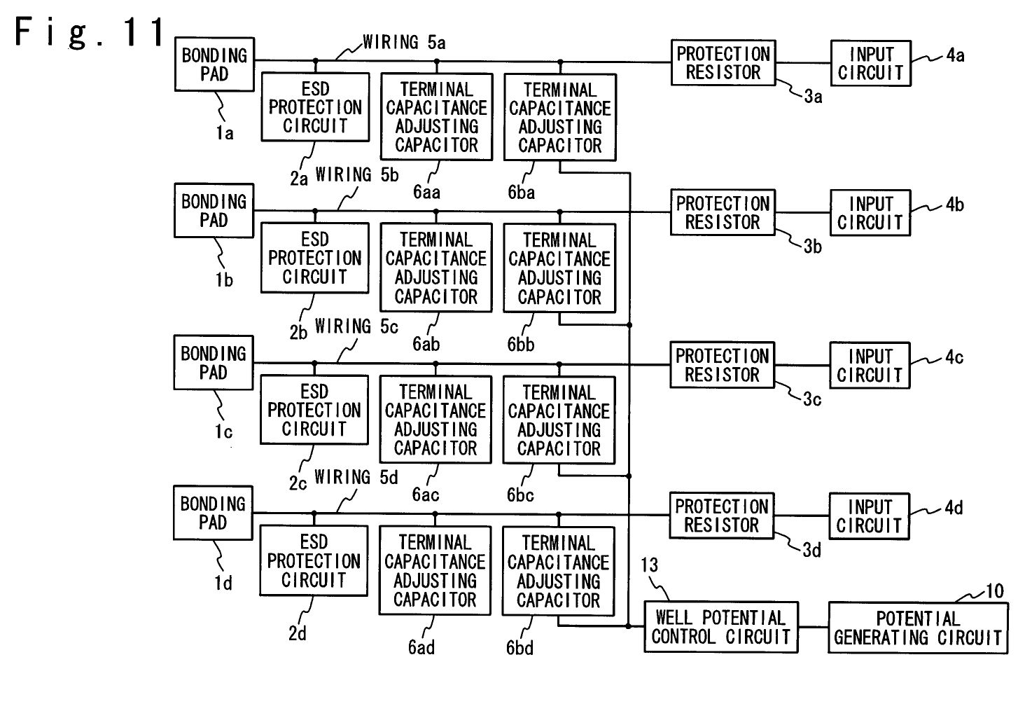

The semiconductor integrated circuit device shown in FIG. 11 is designed such that one well potential control circuit 13 adjusts all of the terminal capacitance by installing the circuits except the well potential control circuit 13 among the circuits shown in FIG. 5A or 5B for each terminal.

This semiconductor integrated circuit device is includes: bonding pads 1a, 1b, 1c and 1d; ESD protection circuits 2a, 2b, 2c and 2d; first terminal capacitance adjusting capacitors 6aa, 6ab, 6ac and 6ad; second terminal capacitance adjusting capacitors 6ba, 6bb, 6bc and 6bd; protection resistors 3a, 3b, 3c and 3d; input circuits 4a, 4b, 4c and 4d; a well potential control circuit 13; and a potential generating circuit 10. In case of using the circuit shown in FIG. 5A, the potential generating circuit 10 is the negative potential generating circuit 10a. In case of using the circuit shown in FIG. 5B1, the potential generating circuit 10 is the positive potential generating circuit 10b.

The bonding pad 1a, the ESD protection circuit 2a, one end of the protection resistor 3a, the first terminal capacitance adjusting capacitor 6aa and the second terminal capacitance adjusting capacitor 6ba are mutually connected through a wiring 5a. The other end of the protection resistor 3a is connected to the input circuit 4a. The second terminal capacitance adjusting capacitor 6ba is connected to the well potential control circuit 13. The well potential control circuit 13 is connected to the potential generating circuit 10.

Similarly, the bonding pad 1b, the ESD protection circuit 2b, one end of the protection resistor 3b, the first terminal capacitance adjusting capacitor 6ab and the second terminal capacitance adjusting capacitor 6bb are mutually connected through a wiring 5b. The other end of the protection resistor 3b is connected to the input circuit 4b. The second terminal capacitance adjusting capacitor 6bb is connected to the well potential control circuit 13.

Similarly, the bonding pad 1c, the ESD protection circuit 2c, one end of the protection resistor 3c, the first terminal capacitance adjusting capacitor 6ac and the second terminal capacitance adjusting capacitor 6bc are mutually connected through a wiring 5c. The other end of the protection resistor 3c is connected to the input circuit 4c. The adjusting capacitor 6bc is connected to the well potential control circuit 13.

Similarly, the bonding pad 1d, the ESD protection circuit 2d, one end of the protection resistor 3d, the first terminal capacitance adjusting capacitor 6ad and the second terminal capacitance adjusting capacitor 6bd are mutually connected through a wiring 5d. The other end of the protection resistor 3d is connected to the input circuit 4d. The adjusting capacitor 6bd is connected to the well potential control circuit 13.

Due to the above-mentioned configuration, in case of using the capacitor that can satisfy the standard of the terminal capacitance value in each package type at the same well potential as the terminal capacitance adjusting capacitor at each terminal, it is possible to set to the terminal capacitance value for each package type only by cutting the fuse of the one well potential control circuit 13.

Incidentally, the semiconductor integrated circuit device shown in FIG. 11 is explained under the assumption that the four terminals are included. However, the number of the terminals is not limited to 4, and it is arbitrary.

### Second Embodiment

A second embodiment of a semiconductor integrated circuit device according to the present invention will be described below with reference to attached drawings.

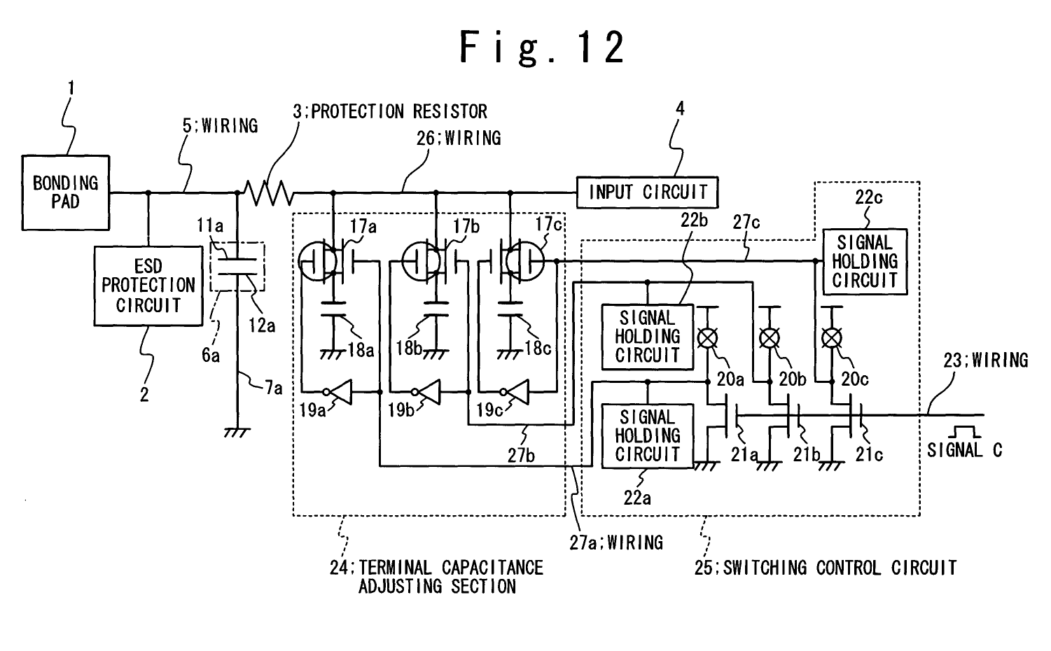

FIG. 12 is a circuit diagram showing a configuration of the second embodiment of the semiconductor integrated circuit device according to the present invention. Here, an input unit of the semiconductor integrated circuit device is shown in FIG. 12. This input unit includes a bonding pad 1, an ESD protection circuit 2, a protection resistor 3, an input circuit 4, a first terminal capacitance adjusting capacitor 6a a terminal capacitance adjusting section 24 and a switching control circuit 25. The first terminal capacitance adjusting capacitor 6a is composed of a diffusion layer 11a and a well 12a and is equal to that of the first embodiment.

The bonding pad 1, the ESD protection circuit 2, one end of the protection resistor 3, and the diffusion layer 11a are mutually connected through a wiring 5. The well 12a is grounded through a wiring 7a. The other end of the protection resistor 3, the input circuit 4 and the terminal capacitance adjusting section 24 are mutually connected through a wiring 26.

The terminal capacitance adjusting section 24 includes a first switch 17a, a second switch 17b, a third switch 17c, a second terminal capacitance adjusting capacitor 18a, a second terminal capacitance adjusting capacitor 18b, a second terminal capacitance adjusting capacitor 18c, a first inverter 19a, a second inverter 19b and a third inverter 19c The first switch 17a, the second switch 17b and the third switch 17c are constituted by transfer gates.

The transfer gate has the known structure composed of an N-type MOSFET and a P-type MOSFET. Input ends of the first to third switches 17a to 17c are connected to a wiring 26. Output ends are connected to ends of the second terminal capacitance adjusting capacitors 18a to 18c, respectively. The other ends of the second terminal capacitance adjusting capacitors 18a to 18c are grounded.

Also, an enable signal is supplied from the switching control circuit 25 through a wiring 27a to a gate of the N-type MOSFET of the first switch 17a. Also, the enable signal is supplied from the switching control circuit 25 through the wiring 27a and the inverter 19a to a gate of the P-type MOSFET of the first switch 17a. Similarly, an enable signal is supplied from the switching control circuit 25 through a wiring 27b to a gate of the N-type MOSFET of the second switch 17b. Also, the enable signal is supplied from the switching control circuit 25 through the wiring 27b and the inverter 19b to a gate of the P-type MOSFET of the second switch 17b. Similarly, the enable signal is supplied from the switching control circuit 25 through a wiring 27c to a gate of the P-type MOSFET of the third switch 17c. Also, the enable signal is supplied from the switching control circuit 25 through the wiring 27c and the inverter 19c to a gate of the N-type MOSFET of the third switch 17c.

The switching control circuit 25 is composed of: a first fuse 20a, a second fuse 20b and a third fuse 20c; a first N-type MOSFET 21a, a second N-type MOSFET 21b and a third N-type MOSFET 21c; and a first signal holding circuit 22a, a second signal holding circuit 22band a third signal holding circuit 22c.

A drain of the first N-type MOSFET 21a is connected through the first fuse 20a to the power supply. A source thereof is grounded. Also, the drain of the first N-type MOSFET 21a is connected to the first signal holding circuit 22a. The first signal holding circuit 22a stores a potential when the first N-type MOSFET 21a is turned on since a pulse-shaped signal C is applied from the outside. The signal held by the first signal holding circuit 22a is sent as the enable signal through the wiring 27a to the terminal capacitance adjusting section 24.

Similarly, a drain of the second N-type MOSFET 21b is connected through the second fuse 20b to the power supply. A source thereof is grounded. Also, the drain of the second N-type MOSFET 21b is connected to the second signal holding circuit 22b. The second signal holding circuit 22b stores a potential when the second N-type MOSFET 21b is turned on since the pulse-shaped signal C is applied from the outside. The signal held by this second signal holding circuit 22b is sent as the enable signal through the wiring 27b to the terminal capacitance adjusting section 24.

Similarly, a drain of the third N-type MOSFET 21c is connected through the third fuse 20c to the power supply. A source thereof is grounded. Also, the drain of the third N-type MOSFET 21c is connected to the third signal holding circuit 22c. The third signal holding circuit 22c stores a potential when the third N-type MOSFET 21c is turned on since the pulse-shaped signal C is applied from the outside. The signal held by this third signal holding circuit 22c is sent as the enable signal through the wiring 27c to the terminal capacitance adjusting section 24.

Incidentally, the first terminal capacitance adjusting capacitor 6a is the capacitor having the terminal capacitance value commonly requested for the respective package types, similarly to that of the above-mentioned first embodiment. The terminal capacitance adjusting section 24 includes the capacitors for adjusting the difference of the terminal capacitance value between the respective package types.

The operation of the input unit of the semiconductor integrated circuit device according to the second embodiment of the present invention will be described below with reference to the drawings.

The first terminal capacitance adjusting capacitor 6a has the fixed capacitance value, similarly to that of the semiconductor integrated circuit device according to the first embodiment. As for the capacitance of the terminal capacitance adjusting section 24, when the power supply of the semiconductor integrated circuit device is turned on, the pulse-shaped signal C shown in FIG. 12 is applied to a wiring 23. Consequently, respective signal levels of the wirings 27a, 27b and 27c are determined and held by the first to third signal holding circuits 22a to 22c, respectively.

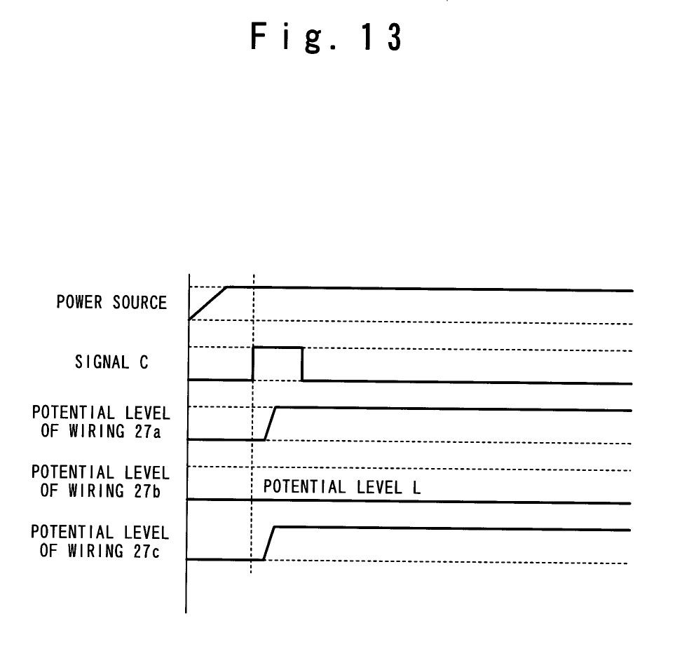

The first to third switches 17a to 17c of the terminal capacitance adjusting section 24 are determined so as to be turned on/off in accordance with the signal levels of the wirings 27a to 27c. Consequently, the terminal capacitance value of the terminal capacitance adjusting section 24 is determined. The signal levels of the wirings 27a to 27c are determined depending on whether or not the first to third fuses 20a to 20c are cut. Each of the signal levels of the wirings 27a to 27c is at a low level (an L level) if the fuse is cut. It is at a high level (an H level) if it is not cut. FIG. 13 is a graph showing an example of change of the potential. In case that the first fuses 20a and the third fuse 20c are not cut and the second fuse 20b is cut, when the signal C is inputted to the wiring 23, the potentials of the wiring 27a and 27c are changed to the H level, while the potential of the wiring 27b remains the L level.

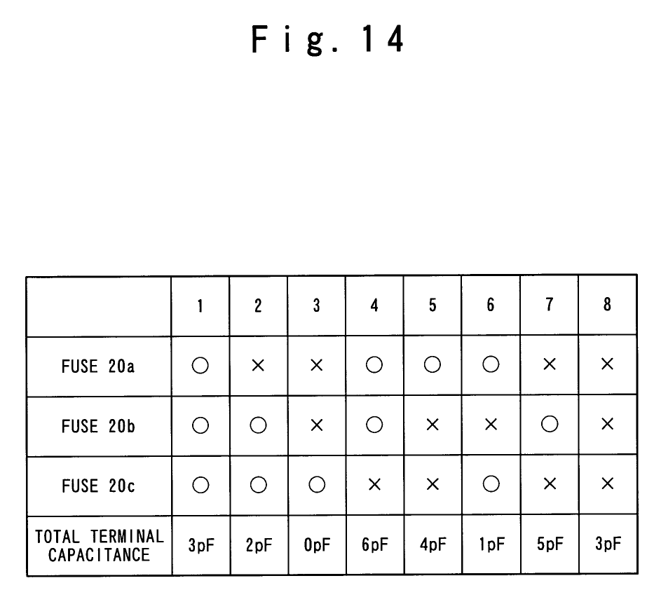

FIG. 14 is a table showing the total values of the capacitance of the terminal capacitance adjusting section 24. The capacitance can be generated in accordance with the presence or absence of the cutting of the first to third fuses 20a to 20c. Here, the second terminal capacitance adjusting capacitor 18a is assumed to be 1 pF, the second terminal capacitance adjusting capacitor 18b is assumed to be 2 pF, and the second terminal capacitance adjusting capacitor 18c is assumed to be 3 pF. An open circle shows not cutting the fuse, and a cross shows cutting the fuse. The terminal capacitance adjusting section 24 can generate 8 kinds of capacitance based on the second terminal capacitance adjusting capacitors 18a to 18c.

How the second terminal capacitance adjusting capacitors 18a, 18b and 18c are connected at an initial state can be determined at the designing stage.

Incidentally, the number of the second terminal capacitance adjusting capacitor is not limited to three, and it is arbitrary. In this case, the variation of the capacitance value is increased such that the accuracy of the adjustment of the terminal capacitance will be increased.

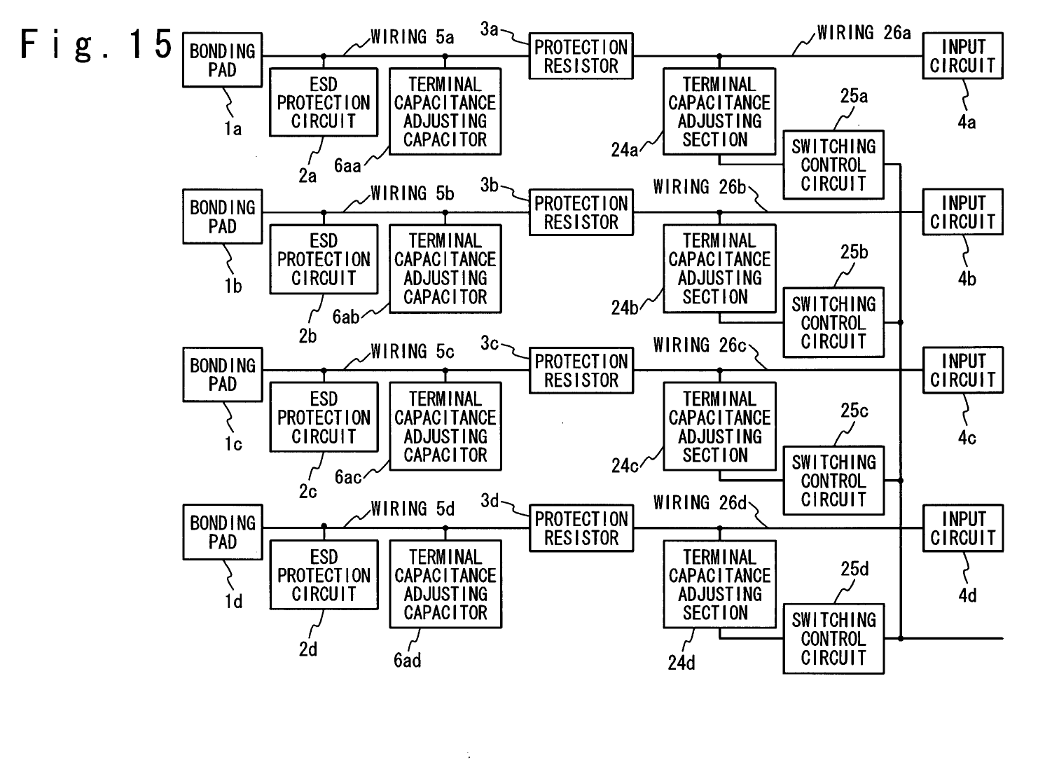

FIGS. 15 to 17 are block diagrams showing the configuration of the semiconductor integrated circuit device according to the second embodiment of the present invention, which is configured by using the circuit shown in FIG. 12.

The semiconductor integrated circuit device shown in FIG. 15 is designed such that the terminal capacitance value can be adjusted for each terminal by installing the circuit shown in FIG. 12 for each terminal (bonding pad 1). This semiconductor integrated circuit device includes: bonding pads 1a, 1b, 1c and 1d; ESD protection circuits 2a, 2b, 2c and 2d; first terminal capacitance adjusting capacitors 6aa, 6ab, 6ac and 6ad; protection resistors 3a, 3b, 3c and 3d; input circuits 4a, 4b, 4c and 4d; terminal capacitance adjusting sections 24a, 24b, 24c and 24d; and switching control circuits 25a, 25b, 25c and 25d.

The bonding pad 1a, the ESD protection circuit 2a, one end of the protection resistor 3a and the first terminal capacitance adjusting capacitor 6aa are mutually connected through the wiring 5a. The other end of the protection resistor 3a, the terminal capacitance adjusting section 24a and the input circuit 4a are mutually connected through a wiring 26a. The terminal capacitance adjusting section 24a is connected to the switching control circuit 25a.

Similarly, the bonding pad 1b, the ESD protection circuit 2b, one end of the protection resistor 3b and the first terminal capacitance adjusting capacitor 6ab are mutually connected through the wiring 5b. The other end of the protection resistor 3b, the terminal capacitance adjusting section 24b and the input circuit 4b are mutually connected through a wiring 26b. The terminal capacitance adjusting section 24b is connected to the switching control circuit 25b.

Similarly, the bonding pad 1c, the ESD protection circuit 2c, one end of the protection resistor 3c and the first terminal capacitance adjusting capacitor 6ac are mutually connected through the wiring 5c. The other end of the protection resistor 3c, the terminal capacitance adjusting section 24c and the input circuit 4c are mutually connected through a wiring 26c. The terminal capacitance adjusting section 24c is connected to the switching control circuit 25c.

Similarly, the bonding pad 1d, the ESD protection circuit 2d, one end of the protection resistor 3d and the first terminal capacitance adjusting capacitor 6ad are mutually connected through the wiring 5d. The other end of the protection resistor 3d, the terminal capacitance adjusting section 24d and the input circuit 4d are mutually connected through a wiring 26d. The terminal capacitance adjusting section 24d is connected to the switching control circuit 25d.

Due to the above-mentioned configuration, the terminal capacitance can be adjusted for each terminal by suitably cutting the fuse included in each of the switching control circuits 25a, 25b, 25c and 25d. Incidentally, FIG. 15 illustrates the configuration when the terminal capacitances are adjusted for the four terminals. However, the number of the terminals is not limited to 4, and it is arbitrary.

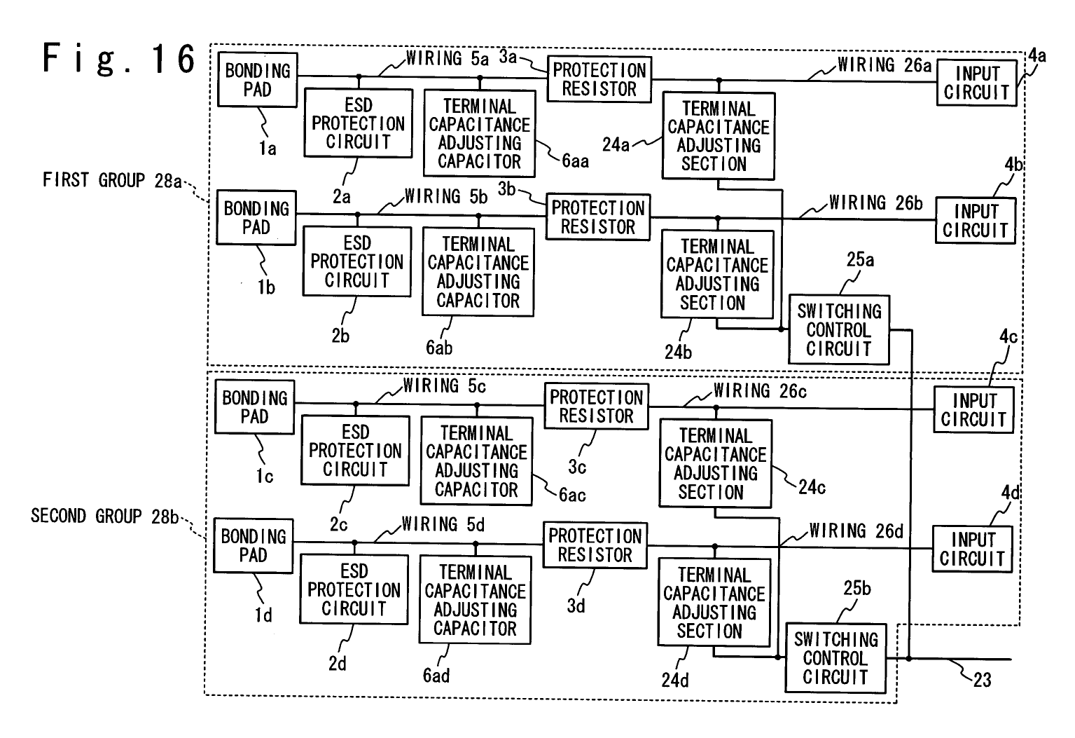

The semiconductor integrated circuit device shown in FIG. 16 includes a first group 28a and a second group 28b designed such that the terminal capacitance value can be adjusted for each terminal group. The terminal capacitance value can be adjusted by installing the circuits except the switching control circuit 25 among the circuits shown in FIG. 12 for each terminal and installing the switching control circuit 25 for each terminal group.

The first group 28a is composed of: bonding pads 1a and 1b; ESD protection circuits 2a and 2b; adjusting capacitors 6aa and 6ab; protection resistors 3a and 3b; terminal capacitance adjusters 24a and 24b; and a switching control circuit 25a.

The second group 28b is composed of: bonding pads 1c and 1d; ESD protection circuits 2c and 2d; adjusting capacitors 6ac and 6ad; protection resistors 3c and 3d; terminal capacitance adjusters 24c and 24d; and a switching control circuit 25b.

As for the first group 28a, the bonding pad 1a, the ESD protection circuit 2a, one end of the protection resistor 3a and the first terminal capacitance adjusting capacitor 6aa are mutually connected through a wiring 5a. The other end of the protection resistor 3a, the terminal capacitance adjusting section 24a and the input circuit 4a are mutually connected through a wiring 26a.

Similarly, the bonding pad 1b, the ESD protection circuit 2b, one end of the protection resistor 3b and the first terminal capacitance adjusting capacitor 6ab are mutually connected through a wiring 5b. The other end of the protection resistor 3b, the terminal capacitance adjusting section 24b and the input circuit 4b are mutually connected through a wiring 26b.

The terminal capacitance adjusting sections 24a and 24b are connected to the switching control circuit 25a.

As for the second group 28b, the bonding pad 1c, the ESD protection circuit 2c, one end of the protection resistor 3c and the first terminal capacitance adjusting capacitor 6ac are mutually connected through a wiring 5c. The other end of the protection resistor 3c, the terminal capacitance adjusting section 24c and the input circuit 4c are mutually connected through a wiring 26c.

Similarly, the bonding pad 1d, the ESD protection circuit 2d, one end of the protection resistor 3d and the first terminal capacitance adjusting capacitor 6ad are mutually connected through a wiring 5d. The other end of the protection resistor 3d, the terminal capacitance adjusting section 24d and the input circuit 4d are mutually connected through a wiring 26d.

The terminal capacitance adjusting sections 24c and 24d are connected to the switching control circuit 25b.

Due to the above-mentioned configuration, the terminal capacitance can be adjusted for each group by suitably cutting the fuse included in each of the switching control circuit 25a of the first group 28a and the switching control circuit 25b of the second group 28b. Thus, the capacitance value can be adjusted by grouping the respective terminals in which the differences of the capacitance values peculiar to the package types are approximately equal.

Incidentally, the semiconductor integrated circuit device shown in FIG. 16 is explained under the assumption that one group includes the two terminals, and the number of the groups is 2. However, the number of the terminals included in the group is not limited to 2, and it is arbitrary. Also, the number of the groups is not limited to 2, and it is arbitrary.

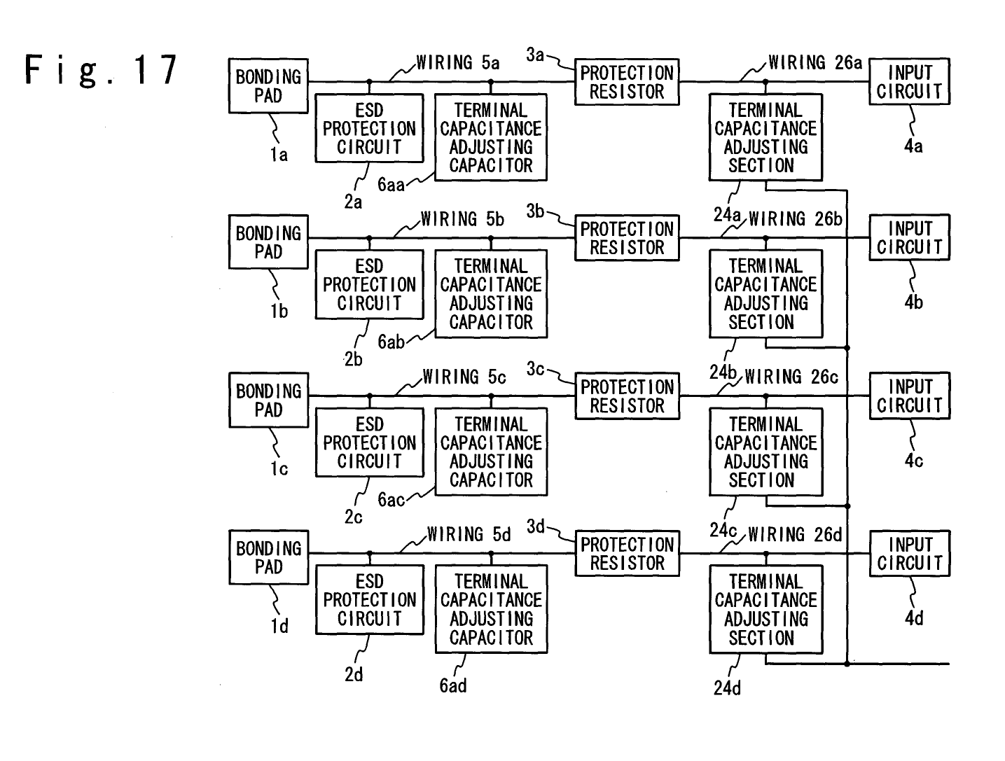

The semiconductor integrated circuit device shown in FIG. 17 is designed such that one switching control circuit 23 adjusts all of the terminal capacitance by installing the circuits except the switching control circuit 23 among the circuits shown in FIG. 12 for each terminal. This semiconductor integrated circuit device is includes: bonding pads 1a, 1b, 1c and 1d; ESD protection circuits 2a, 2b, 2c and 2d; first terminal capacitance adjusting capacitors 6aa, 6ab, 6ac and 6ad; protection resistors 3a, 3b, 3c and 3d; input circuits 4a, 4b, 4c and 4d; terminal capacitance adjusting sections 24a, 24b, 24c and 24d; and a switching control circuit 25.

The bonding pad 1a, the ESD protection circuit 2a, one end of the protection resistor 3a and the first terminal capacitance adjusting capacitor 6aa are mutually connected through a wiring 5a. The other end of the protection resistor 3a, the terminal capacitance adjusting section 24a and the input circuit 4a are mutually connected through a wiring 26a.

Similarly, the bonding pad 1b, the ESD protection circuit 2b, one end of the protection resistor 3b and the first terminal capacitance adjusting capacitor 6ab are mutually connected through a wiring 5b. The other end of the protection resistor 3b, the terminal capacitance adjusting section 24b and the input circuit 4b are mutually connected through a wiring 26b.

Similarly, the bonding pad 1c, the ESD protection circuit 2c, one end of the protection resistor 3c and the first terminal capacitance adjusting capacitor 6ac are mutually connected through a wiring 5c. The other end of the protection resistor 3c, the terminal capacitance adjusting section 24c and the input circuit 4c are mutually connected through a wiring 26c.

Similarly, the bonding pad 1d, the ESD protection circuit 2d, one end of the protection resistor 3d and the first terminal capacitance adjusting capacitor 6ad are mutually connected through a wiring 5d. The other end of the protection resistor 3d, the terminal capacitance adjusting section 24d and the input circuit 4d are mutually connected through a wiring 26d. The switching control circuit 25 is connected to the terminal capacitance adjusters 24a, 24b, 24c and 24d.

Due to the above-mentioned configuration, in case of using the capacitors that can satisfy the standard of the terminal capacitance values in the respective package types for the terminal capacitance adjusting section 24a, 24b, 24c and 24d at the respective terminals, it is possible to set to the terminal capacitance values for the respective package types only by cutting the fuse of the switching control circuit 25.

Incidentally, the semiconductor integrated circuit device shown in FIG. 17 is explained under the assumption that the four terminals are included. However, the number of the terminals is not limited to 4, and it is arbitrary.

### Third Embodiment

Next, a third embodiment of a semiconductor integrated circuit device according to the present invention will be described below with reference to attached drawings.

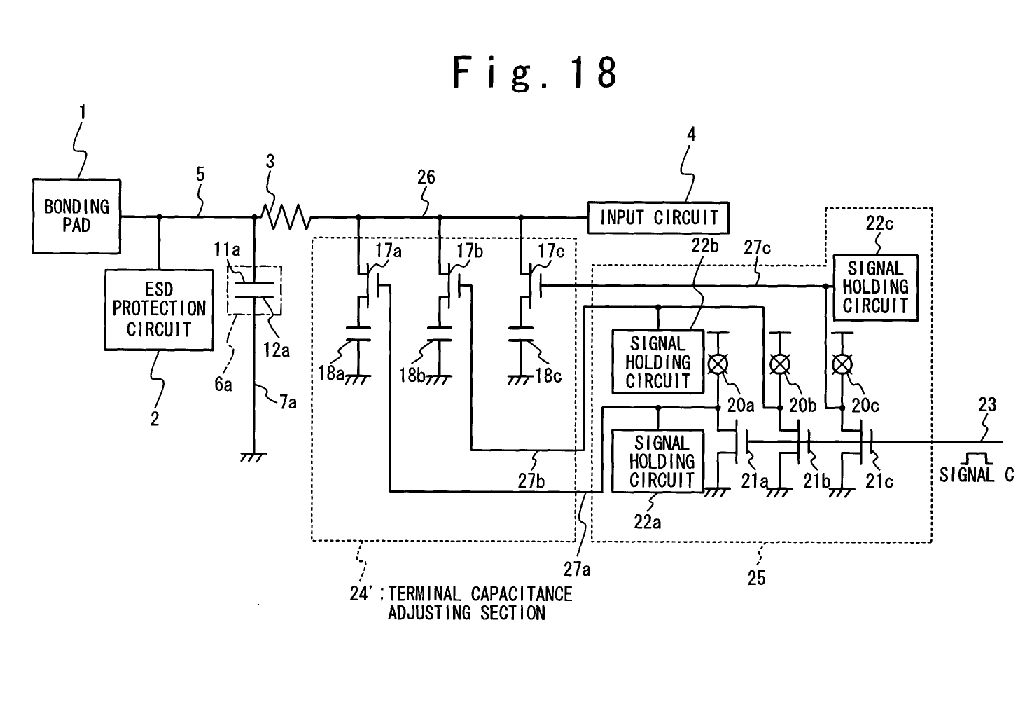

FIG. 18 is a circuit diagram showing a configuration of the third embodiment of the semiconductor integrated circuit device according to the present invention.

The semiconductor integrated circuit device according to a third embodiment is designed such that the terminal capacitance adjusting section 24 of the second embodiment is changed.

That is, in a terminal capacitance adjusting section 24′ of the third embodiment, a first N-type MOSFET 17a, a second N-type MOSFET 17b and a third N-type MOSFET 17c are used as the first switch 17a, the second switch 17b and the third switch 17c in the second embodiment, respectively, as shown in FIG. 18.

This configuration enables the first to third N-type MOSFETs 17a to 17c to be turned on/off in accordance with the signals sent through the wirings 27a to 27c. Thus, it is operated similarly to the second embodiment. Hence, it provides the function and the effect, which are similar to those of the second embodiment.

### Fourth Embodiment

Next, a fourth embodiment of a semiconductor integrated circuit device according to the present invention will be described below with reference to attached drawings.

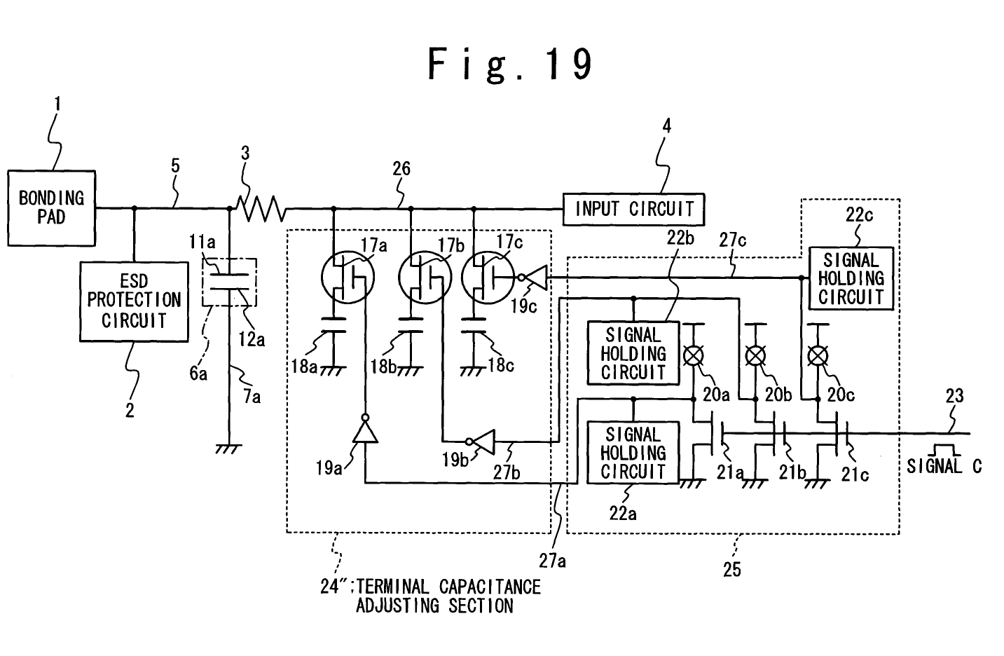

FIG. 19 is a circuit diagram showing a configuration of the fourth embodiment of the semiconductor integrated circuit device according to the present invention.

The semiconductor integrated circuit device according to a fourth embodiment is designed such that the terminal capacitance adjusting section 24 of the second embodiment is changed.

That is, in a terminal capacitance adjusting section 24″ of the fourth embodiment, a first P-type MOSFET 17a, a second P-type MOSFET 17b and a third P-type MOSFET 17c are used as the first switch 17a, the second switch 17b and the third switch 17c in the second embodiment, respectively, as shown in FIG. 14. Then, inverters 19a, 19b and 19c are respectively installed in order to invert signals to be supplied to respective bases of the first to third P-type MOSFETs 17a to 17c.

This configuration enables the first to third P-type MOSFETs 17a to 17c to be turned on/off in accordance with the signals sent through the wirings 27a to 27c. Thus, it is operated similarly to the second embodiment. Hence, it provides the function and the effect, which are similar to those of the second embodiment.

### Fifth Embodiment

Next, a fifth embodiment of a semiconductor integrated circuit device according to the present invention will be described below with reference to attached drawings.

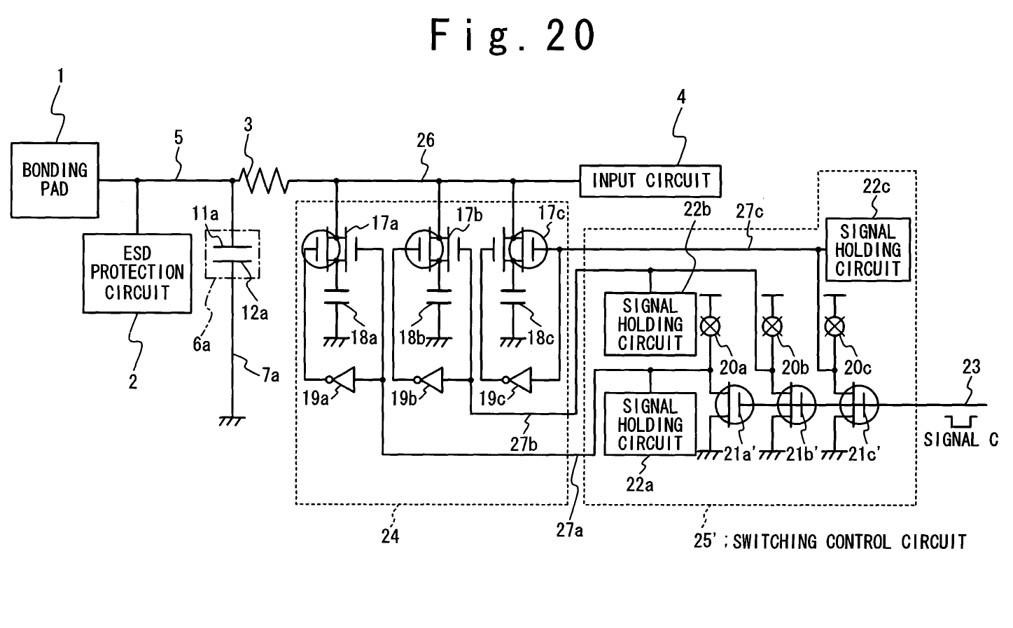

FIG. 20 is a circuit diagram showing a configuration of the fifth embodiment of the semiconductor integrated circuit device according to the present invention.

The semiconductor integrated circuit device according to a fifth embodiment is designed such that the switching control circuit 25 of the second embodiment is changed.

That is, in a switching control circuit 25′ of the fifth embodiment, a first P-type MOSFET 21a′, a second P-type MOSFET 21b′ and a third P-type MOSFET 21c′ are used instead of the first N-type MOSFET 21a, the second N-type MOSFET 21b and the third N-type MOSFET 21c in the second embodiment, respectively, as shown in FIG. 15. Then, a pulse-shaped signal C′ whose phase is inverted from that of the pulse-shaped signal C in the second embodiment is supplied to respective bases of the first to third P-type MOSFETs 21a′ to 21c′.

This configuration enables the first to third P-type MOSFETs 21a′ to 21c′ to be turned on/off in accordance with the presence or absence of the cutting of the first to third fuses 20a to 20c. Thus, it is operated similarly to the second embodiment. Hence, it provides the function and the effect, which are similar to those of the second embodiment.

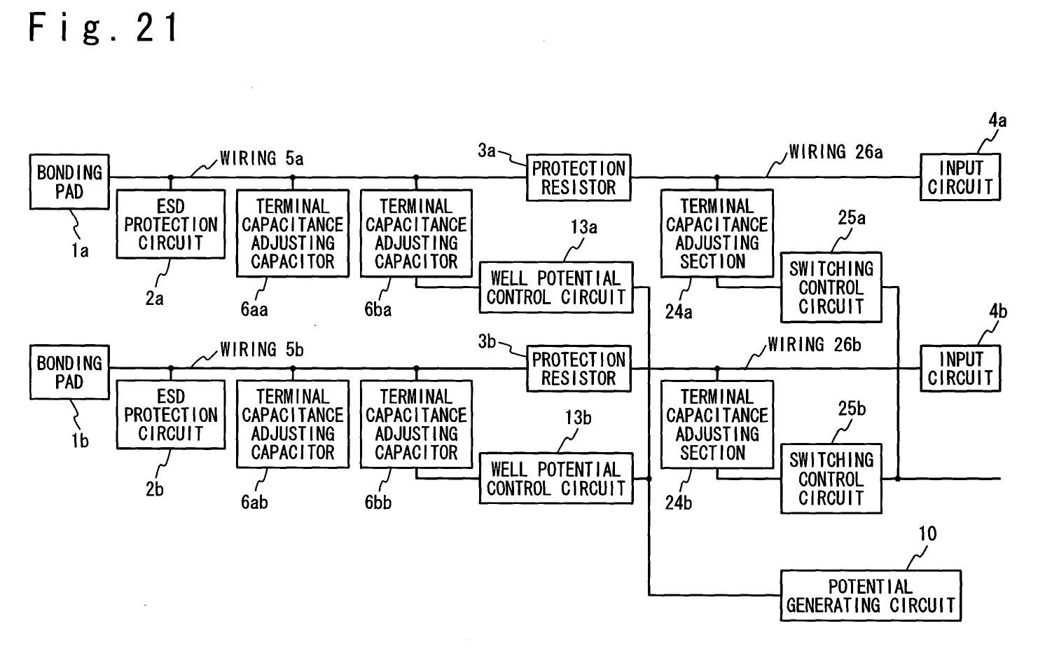

FIG. 21 is a block diagram showing a configuration of another embodiment of the semiconductor integrated circuit device according to the present invention. As shown in FIG. 21, the first embodiment may be combined with the second embodiment. Also, the at least one of the third to the fifth embodiments may be combined with the second embodiment.

As mentioned above, in the semiconductor integrated circuit device according to the embodiments of the present invention, the terminal capacitance adjusting capacitor is configured by the diffusion layer within the well. Thus, the capacitor can be placed before the protection resistor to thereby reduce the delay in the input signal and further improve the property. This is important in the present situation requiring the operation at the high frequency of the semiconductor integrated circuit device. The delay time (T) caused by the conventional protection resistor and capacitor is 500 Ω×2 pF=1 ns.

Also, the installation of the control circuit, which controls the potential of the well, enables the terminal capacitance value to be adjusted even after the finish of the diffusing process. Thus, it is not necessary to carry out the modification design and re-produce the reticle.

Also, the terminal capacitance adjusting section and the switching control circuit for controlling the switches included in this terminal capacitance adjusting section are installed in order to switch the terminal capacitance adjusting capacitor. Thus, the terminal capacitance value can be adjusted even after the finish of the diffusion process. Hence, it is not necessary to carry out the modification design and re-produce the reticle.

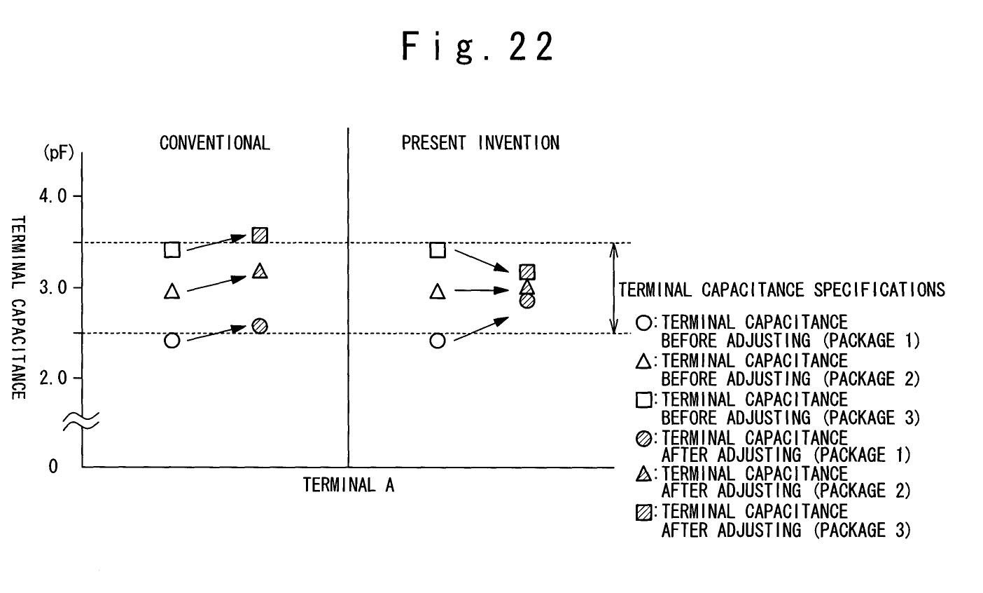

Moreover, since the terminal capacitance value can be adjusted after the finish of the diffusion, on the same semiconductor chip, it is possible to cope with the plurality of package types. FIG. 22 is a view showing the comparison between the terminal capacitance when the conventional technique is used and the terminal capacitance when the technique according to the present invention is used. When the conventional technique is used, the terminal capacitance after the adjustment is uniformly increased independently of the package type, which brings about the case that it becomes outside the standard of the terminal capacitance. On the contrary, when the technique according to the present invention is used, the terminal capacitance value can be adjusted to any capacitance value. Thus, the terminal capacitance can fall in the standard of the terminal capacitance.

As detailed above, according to the present invention, it is possible to provide the semiconductor integrated circuit device, in which the terminal capacitance can be accurately adjusted without any increase in the chip size, in the short time and at the cheap price.

1. A semiconductor integrated circuit device comprising:
a terminal; and
a first capacitance adjusting section which is connected to a wiring between said terminal and a protection resistor in front stage of an internal circuit,
wherein said first capacitance adjusting section adjusts terminal capacitance of said terminal, based on capacitance of said first capacitance adjusting section.

2. The semiconductor integrated circuit device according to claim 1, further comprising:
a protection circuit which is connected to said wiring between said terminal and said first capacitance adjusting section and protects said internal circuit.

3. The semiconductor integrated circuit device according to claim 1, wherein said first capacitance adjusting section comprises a first adjusting capacitor which adjusts said terminal capacitance,
said first adjusting capacitor comprises:
a first semiconductive portion which is composed of a first well region formed in a substrate with said internal circuit and having a conductive type opposite to that of said substrate, and
a second semiconductive portion which is opposite to said first semiconductive portion and is composed of a first diffusion layer region formed in said first well region and having the same conductive type as that of said substrate.

4. The semiconductor integrated circuit device according to claim 3, further comprising:
a well potential control section,
wherein said first capacitance adjusting section further comprises a second adjusting capacitor which adjusts said terminal capacitance based on controlling a well region potential by said well potential control section,
said second adjusting capacitor comprises:
a third semiconductive portion which is composed of a second well region formed in said substrate and having a conductive type opposite to that of said substrate,
a fourth semiconductive portion which is opposite to said third semiconductive portion and is composed of a second diffusion layer region formed in said second well region and having the same conductive type as that of said substrate, and
said well potential control section controls said well region potential of said second well region.

5. The semiconductor integrated circuit device according to claim 4, wherein said well potential control section comprises:
a plurality of resistors which are connected in series to each other between two potential electrodes; and
a plurality of switches each of which is connected in parallel to each of said plurality of resistors,
said well potential control section controls said well region potential by controlling each one of said plurality of switches.

6. The semiconductor integrated circuit device according to claim 5, further comprising:
a plurality of said terminals; and
a plurality of said first capacitance adjusting sections, each of which is connected to said wiring between each of said plurality of terminals and each of a plurality of said protection resistors,
wherein said well potential control section controls each of a plurality of said well region potentials.

7. The semiconductor integrated circuit device according to claim 2, wherein said first capacitance adjusting section comprises a first adjusting capacitor which adjusts said terminal capacitance,
said first adjusting capacitor comprises:
a first semiconductive portion which is composed of a first well region formed in a substrate with said internal circuit and having a conductive type opposite to that of said substrate, and
a second semiconductive portion which is opposite to said first semiconductive portion and is composed of a first diffusion layer region formed in said first well region and having the same conductive type as that of said substrate.

8. The semiconductor integrated circuit device according to claim 7, further comprising:
a well potential control section,
wherein said first capacitance adjusting section further comprises a second adjusting capacitor which adjusts said terminal capacitance based on controlling a well region potential by said well potential control section,
said second adjusting capacitor comprises:
a third semiconductive portion which is composed of a second well region formed in said substrate and having a conductive type opposite to that of said substrate,
a fourth semiconductive portion which is opposite to said third semiconductive portion and is composed of a second diffusion layer region formed in said second well region and having the same conductive type as that of said substrate, and
said well potential control section controls said well region potential of said second well region.

9. The semiconductor integrated circuit device according to claim 8, wherein said well potential control section comprises:
a plurality of resistors which are connected in series to each other between two potential electrodes; and
a plurality of switches each of which is connected in parallel to each of said plurality of resistors,
said well potential control section controls said well region potential by controlling each one of said plurality of switches.

10. The semiconductor integrated circuit device according to claim 9, further comprising:
a plurality of said terminals; and
a plurality of said first capacitance adjusting sections each of which is connected to each of a plurality of said wirings between each of said plurality of terminals and each of a plurality of said protection resistors,
wherein said well potential control section controls each of a plurality of said well region potentials.

11. The semiconductor integrated circuit device according to claim 1, further comprising:
a second capacitance adjusting section which is connected to a wiring between said first capacitance adjusting section and said internal circuit, wherein said second capacitance adjusting section adjusts said terminal capacitance based on capacitance of said second capacitance adjusting section; and
a switching control section which controls said capacitance of said second capacitance adjusting section.

12. The semiconductor integrated circuit device according to claim 11, wherein said switching control section comprises:
a plurality of switches each of which outputs signal potentials corresponding to turn on and off of said each of plurality of switches, and
a plurality of signal holding sections each of which holds corresponding each of a plurality of said signal potentials,
wherein said switching control section controls said capacitance of said second capacitance adjusting section based on said plurality of signal potentials.

13. The semiconductor integrated circuit device according to claim 12, wherein said second capacitance adjusting section comprises:
a plurality of third adjusting capacitors each of which capacitance is variable based on corresponding said each of said plurality of signal potentials,
wherein said second capacitance adjusting section adjusts said plurality of third adjusting capacitors based on said plurality of signal potentials.

14. The semiconductor integrated circuit device according to claim 13, further comprising:
a plurality of said terminals; and
a plurality of said second capacitance adjusting sections each of which is connected to each of a plurality of said wirings between each of said plurality of said first capacitance adjusting sections and each of a plurality of said internal circuits,
wherein said switching control section controls each of a plurality of said capacitances of said plurality of second capacitance adjusting sections.

15. The semiconductor integrated circuit device according to claim 3, further comprising:
a second capacitance adjusting section which is connected to a wiring between said first capacitance adjusting section and said internal circuit, wherein said second capacitance adjusting section adjusts said terminal capacitance based on capacitance of said second capacitance adjusting section; and
a switching control section which controls said capacitance of said second capacitance adjusting section.

16. The semiconductor integrated circuit device according to claim 15, wherein said switching control section comprises:
a plurality of switches each of which outputs signal potentials corresponding to turn on and off of said each of plurality of switches, and
a plurality of signal holding sections each of which holds corresponding each of a plurality of said signal potentials,
wherein said switching control section controls said capacitance of said second capacitance adjusting section based on said plurality of signal potentials.

17. The semiconductor integrated circuit device according to claim 16, wherein said second capacitance adjusting section comprises:
a plurality of third adjusting capacitors each of which capacitance is variable based on corresponding said each of said plurality of signal potentials,
wherein said second capacitance adjusting section adjusts said plurality of third adjusting capacitors based on said signal potential.

18. The semiconductor integrated circuit device according to claim 17, further comprising:
a plurality of said terminals; and
a plurality of said second capacitance adjusting sections each of which is connected to each of a plurality of said wirings between each of said plurality of said first capacitance adjusting sections and each of a plurality of said internal circuits,
wherein said switching control section controls each of a plurality of said capacitances of said plurality of second capacitance adjusting sections.
